(19) United States
(12) Patent Application Publication
(10) Pub. No.: US 2015/0282313 A1
(43) Pub. Date: Oct. 1, 2015

(54) WIRING BOARD AND WIRING BOARD PRODUCTION METHOD

(71) Applicant: KABUSHIKI KAISHA TOYOTA JIDOSHOKKI, Aichi (JP)

(72) Inventors: Kiminori Ozaki, Kariya-shi (JP); Yasuhiro Koike, Kariya-shi (JP); Hiroaki Asano, Kariya-shi (JP); Hitoshi Shimazu, Kariya-shi (JP); Tomoaki Asai, Nagoya-shi (JP)

(73) Assignee: KABUSHIKI KAISHA TOYOTA JIDOSHOKKI, Aichi (JP)

(21) Appl. No.: 14/428,526

(22) PCT Filed: Sep. 17, 2013
(86) PCT No.: PCT/JP2013/074985

§ 371 Date: Mar. 17, 2015

(30) Foreign Application Priority Data
Sep. 20, 2012 (JP) 2012-207388

(51) Int. Cl. H05K 1/11; H05K 3/00; H05K 1/02; H05K 3/36; H05K 1/18; H05K 1/14

(52) U.S. Cl. CPC H05K 1/11; H05K 1/181; H05K 1/142; H05K 1/0213; H05K 3/36; H05K 3/0073; H05K 2201/09145; H05K 2203/043

(57) ABSTRACT

A wiring board includes a first substrate including a first surface and a second substrate including a first surface. A solder hole is arranged at least in the first surface of the first substrate. A solder hole is arranged at least in the first surface of the second substrate. The second substrate is coupled to the first substrate. The first substrate and the second substrate are electrically connected with each other. The first surface of the first substrate and the first surface of the second substrate are flush with each other and configured such that a part of one surface of a mask is placed on the first surface of the first substrate and another part of the surface of the mask is placed on the first surface of the second substrate.

### TECHNICAL FIELD

The present invention relates to a wiring board and a wiring board production method.

### BACKGROUND ART

Patent Document 1 discloses a semiconductor device including a metal base, a first mounting substrate formed on the metal base, and a second mounting substrate formed on the metal base. A power semiconductor element is mounted on the first mounting substrate. A control circuit element is mounted on the second mounting substrate. Traces are formed on the first or second mounting substrate to extend outside the substrate. The extended traces electrically connect the first and second mounting substrates with each other.

### PRIOR ART DOCUMENT

### Patent Document

Patent Document 1: Japanese Laid-Open Patent Publication No. 7-74306

### SUMMARY OF THE INVENTION

### Problems that the Invention is to Solve

When the traces that lie outside the substrates electrically connect the first and second mounting substrates with each other, the traces create a step at the connection between the first mounting substrate and the second mounting substrate. Due to this, components need to be mounted on the first and second mounting substrates by solder printing and reflowing. This increases production costs.

Known methods for electrically connecting two substrates (a thick copper power substrate 100 and a control substrate 200 in FIG. 8) with each other include a method for connecting the substrates with a connector 300 or by fixing a bus bar with screws. In such a method, components are mounted on the substrates 100 and 200 by solder printing and reflowing. This increases production costs.

An objective of the present invention is to provide a wiring board and a wiring board production method that allow mass-soldering to be performed on a plurality of substrates.

### Means for Solving the Problems

According to one aspect of the present invention to achieve the above objective, a wiring board is provided. The wiring board includes a first substrate including a first surface and a second substrate including a first surface. A solder hole is arranged at least in the first surface of the first substrate. A solder hole is arranged at least in the first surface of the second substrate. The second substrate is coupled to the first substrate. The first substrate and the second substrate are electrically connected with each other. The first surface of the first substrate and the first surface of the second substrate are flush with each other and configured such that a part of one surface of a mask is placed on the first surface of the first substrate and another part of the surface of the mask is placed on the first surface of the second substrate.

According to another aspect of the present invention, a wiring board production method is provided. The method includes a coupling process, a first placement process, a solder application process, and a removal process, a second placement process, and a reflowing process. The coupling process couples a first substrate to a second substrate such that a first surface of the first substrate, which has a solder hole, is flush with a first surface of the second substrate, which has a solder hole. The first placement process places a mask on the first surface of the first substrate and the first surface of the second substrate. A part of one surface of the mask is placed on the first surface of the first substrate, and another part of the surface of the mask is placed on the first surface of the second substrate. The solder application process applies solder onto the first substrate and the second substrate through the mask. The removal process removes the mask. The second placement process places a component on at least a part of the applied solder. The reflowing process mass-solders the component by reflowing.

### BRIEF DESCRIPTION OF THE DRAWINGS

FIG. 1 is a plan view of a wiring board according to one embodiment of the present invention;

FIG. 2 is a cross-sectional view taken along line 2-2 in FIG. 1;

FIG. 3 is an enlarged view of part B in FIG. 1;

FIG. 4 is a cross-sectional view taken along line 4-4 in FIG. 3;

FIGS. 5A and 5B are explanatory longitudinal sectional views illustrating a wiring board production method;

FIGS. 6A and 6B are explanatory longitudinal sectional views illustrating the wiring board production method;

FIG. 7A is an explanatory longitudinal sectional view illustrating the wiring board production method;

FIG. 7B is a longitudinal sectional view of a wiring board according to a modification; and

FIG. 8 is an explanatory perspective view of a conventional wiring board, describing the objective.

### MODES FOR CARRYING OUT THE INVENTION

A wiring board and a wiring board production method according to one embodiment of the present invention will now be described with reference to the drawings.

In the drawings, a horizontal plane is defined with the X and Y directions, and a vertical direction is defined as the Z direction.

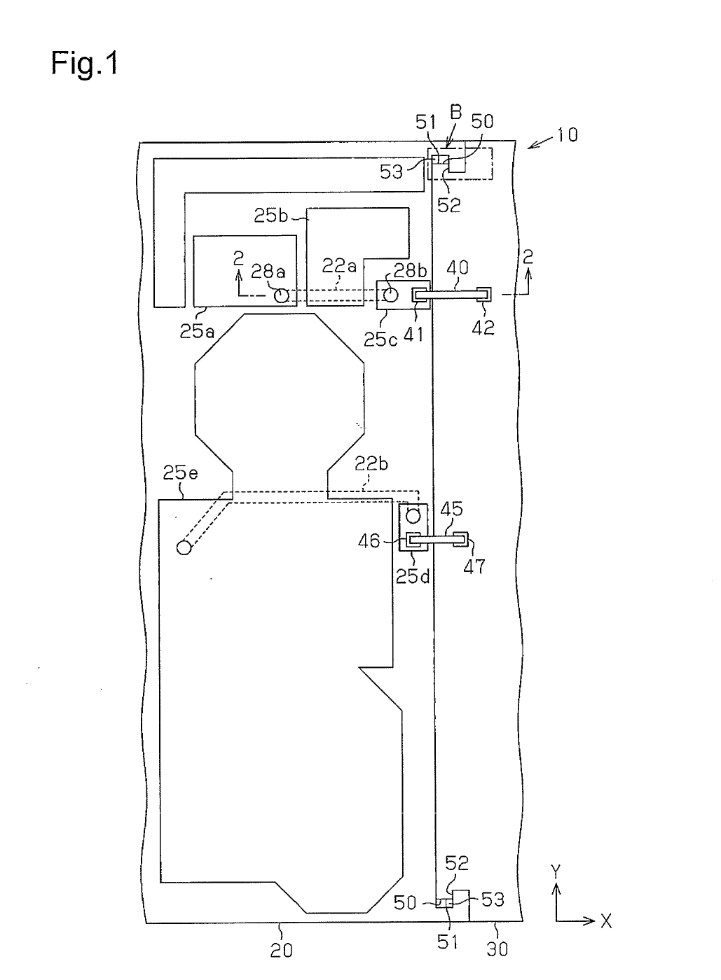

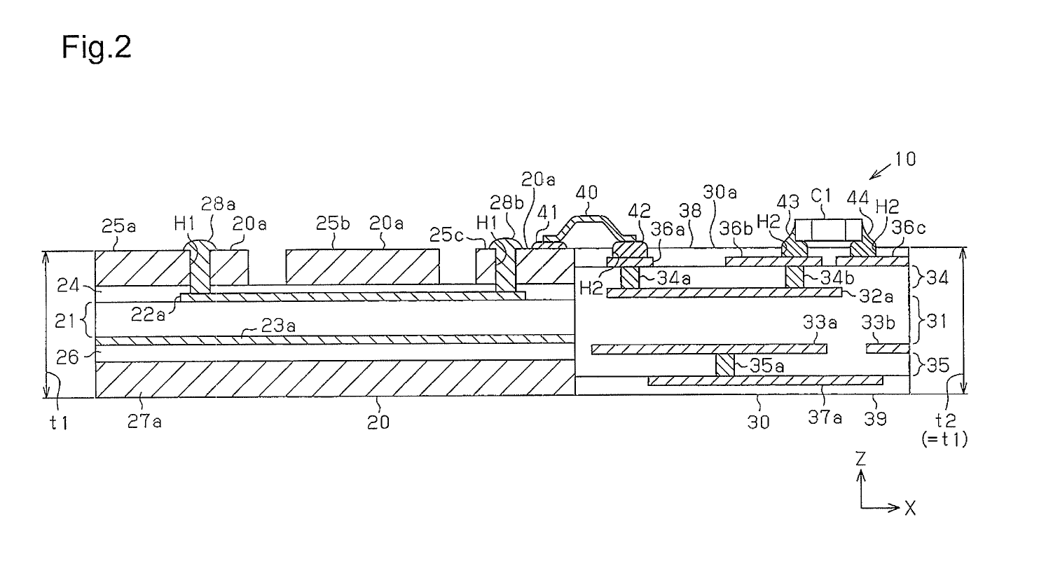

FIGS. 1 and 2 show a wiring board 10, which includes a first substrate 20 and a second substrate 30. The first substrate 20 is a thick copper substrate. The second substrate 30 is a control board. The substrates 20 and 30 are different types of substrates, i.e., have different structures. The first substrate 20 has components such as power elements, and the second substrate 30 has components such as integrated circuit chips.

FIG. 2 shows the first substrate 20, which includes an inner layer pattern 22a formed on the top surface of a core material 21 and an inner layer pattern 23a formed on the bottom surface of the core material 21. Thick copper patterns 25a, 25b, and 25c are adhered to the top surface of the core material 21 with an adhesive sheet 24. A thick copper pattern 27a is adhered to the bottom surface of the core material 21 with an adhesive sheet 26.

The thick copper pattern 25a, the thick copper pattern 25b, and the thick copper pattern 25c are spaced from one another in the first substrate 20. The thick copper pattern 25a and the thick copper pattern 25c each include a solder hole H1.

The second substrate 30 includes an insulative layer 31. An inner layer wiring pattern 32a is formed on the top surface of the insulative layer 31. Inner layer wiring patterns 33a and 33b are formed on the bottom surface of the insulative layer 31. The top surface of the insulative layer 31 is laminated with an insulative layer 34. The bottom surface of the insulative layer 31 is laminated with an insulative layer 35. Wiring patterns 36a, 36b, and 36c are formed on the top surface of the insulative layer 34. A wiring pattern 37a is formed on the bottom surface of the insulative layer 35.

A via hole 34a connects the wiring pattern 36a with the inner layer wiring pattern 32a. A via hole 34b connects the wiring pattern 36b with the inner layer wiring pattern 32a. Thus, the wiring pattern 36a and the wiring pattern 36b are electrically connected with each other through the inner layer wiring pattern 32a. A via hole 35a connects the wiring pattern 37a with the inner layer wiring pattern 33a.

A resist 38 covers the wiring patterns 36a, 36b, and 36c on the top surface of the insulative layer 34. A resist 39 covers the wiring pattern 37a on the bottom surface of the insulative layer 35. Solder holes H2 are formed in the resist 38.

The thickness t1 of the first substrate 20 is the same as the thickness t2 of the second substrate 30. The first substrate 20 and the second substrate 30 are placed on one plane to line up in the X direction and have side surfaces (end surfaces) that contact with each other. In other words, the first substrate 20 and the second substrate 30 are placed side by side without overlapping. In this manner, the first substrate 20 is coupled to the second substrate 30.

When the first substrate 20 and the second substrate 30 are coupled to each other, i.e., are integrated, an upper surface 20a of the first substrate 20 and an upper surface 30a of the second substrate 30 are located at the same height (in the Z direction).

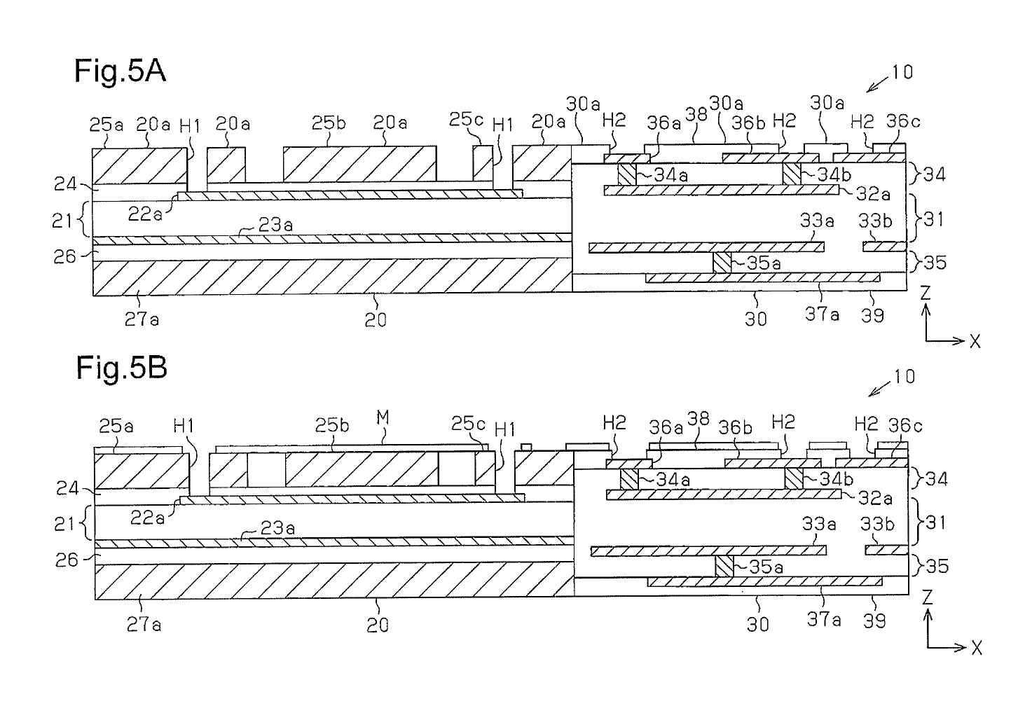

The first substrate 20 includes the upper surface 20a as the first surface, and the solder holes H1 are arranged in the first substrate. The second substrate 30 includes the upper surface 30a as the first surface, and the solder holes H2 are arranged in the first substrate. The first substrate 20 is coupled to the second substrate 30 such that the bottom surfaces of the substrates 20 and 30 are placed on one plane and the upper surface 20a of the first substrate 20 is flush with the upper surface 30a of the second substrate 30. In other words, the upper surface 20a and the upper surface 30a are flush with each other and configured such that a part of one surface of a mask M (refer to FIG. 5A) is placed on the upper surface 20a of the first substrate 20 and another part of the surface of the mask M is placed on the upper surface 30a of the second substrate 30. FIG. 2 shows a chip C1 as a surface-mount component, which is mass-soldered to the second substrate 30 with solder 43 and 44, and a jumper wire 40, which is mass-soldered to the first substrate 20 and the second substrate 30 with the solder 41 and 42.

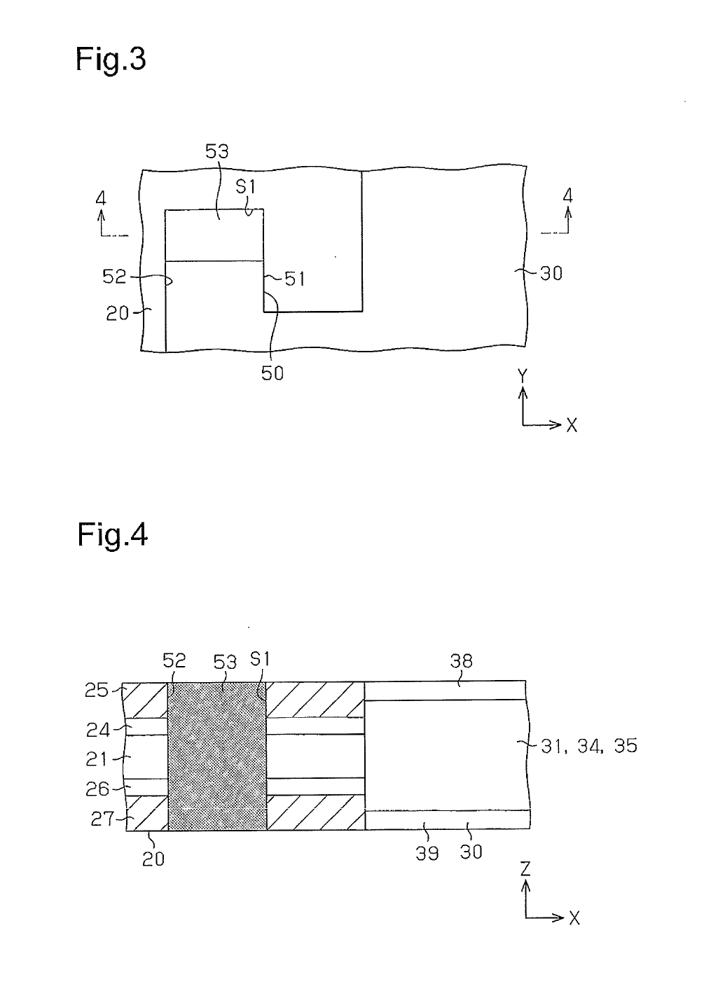

The wiring board 10 includes positioning portions 50, which position the first substrate 20 and the second substrate 30 using the relationship between projections and recesses of the positioning portions 50. FIGS. 3 and 4 show a positioning portion 50, which is configured such that a projection 51 arranged in the second substrate 30 engages with a recess 52 arranged in the first substrate 20. The projection 51 extends in the Y direction, and the recess 52 extends in the Y direction. The projection 51 of the second substrate 30 fits in the recess 52 of the first substrate 20.

The positioning portions 50 are arranged at two positions as shown in FIG. 1. The two positioning portions 50 have the same structure. The positioning portions 50 restrict horizontal movement of the first and second substrates 20 and 30, i.e., movement in the X and Y directions. This prevents displacement of the substrates 20 and 30.

Each positioning portion 50 has a space S1 for placing adhesive 53 as a connection member. In particular, the space S1 is formed between the distal surface of the projection 51 and the bottom surface of the recess 52 as viewed from the top in FIG. 3. The space S1 vertically extends as shown in FIG. 4. The adhesive 53 is filled in the space S1. The adhesive 53 connects the first substrate 20 with the second substrate 30.

Components are soldered to the top surface of the wiring board 10 (the first substrate 20 and the second substrate 30). In particular, components such as power elements and electrolytic capacitors are mounted on the upper surface 20a of the first substrate 20. Components such as IC chips are mounted on the upper surface 30a of the second substrate 30. In the case of FIG. 2, a cooling device is placed below the thick copper pattern 27a so that a heat releasing path is formed through the thick copper pattern 27a.

In FIG. 2, the thick copper pattern 25a and the thick copper pattern 25c are electrically connected with each other through the inner layer pattern 22a. In particular, solder 28a electrically connects the thick copper pattern 25a with the inner layer pattern 22a, and solder 28b electrically connects the thick copper pattern 25c with the inner layer pattern 22a.

The jumper wire 40 is mounted on the upper surfaces 20a and 30a of the first and second substrates 20 and 30. The jumper wire 40 electrically connects the first substrate 20 and the second substrate 30 with each other. In particular, solder 41 and 42 connects the thick copper pattern 25c of the first substrate 20 with the wiring pattern 36a of the second substrate 30. Similarly, FIG. 1 shows a jumper wire 45, which has one end connected to a thick copper pattern 25d of the first substrate 20 with solder 46 and the other end connected to the second substrate 30 with solder 47. The thick copper pattern 25d of the first substrate 20 is connected with a thick copper pattern 25e through an inner layer pattern 22b.

Thus, the jumper wires 40 and 45 electrically connect the first substrate 20 with the second substrate 30 using the patterns 25c and 25d formed of a copper board, which is laid on a patterned copper-plated laminated board via the adhesive sheets 24 and 26.

Operation of the wiring board 10 will now be described.

To produce the wiring board 10, the first substrate 20 and the second substrate 30 are prepared. The second substrate 30 includes the projection 51, and the first substrate 20 includes the recess 52. The projection 51 is engaged with the recess 52. The adhesive 53 is applied to fill the space S1 of the positioning portion 50 between the first substrate 20 and the second substrate 30. As shown in FIG. 5A, the first substrate 20 and the second substrate 30 are placed on one plane so that solder joining surfaces are flush with each other. That is, the upper surface 20a becomes flush with the upper surface 30a. Thus, the first substrate 20 is coupled to the second substrate 30 such that the first surface 20a of the first substrate 20, which has the solder holes H1, is flush with the first surface 30a of the second substrate 30, which has the solder holes H2. In other words, the upper surface 20a and the upper surface 30a are flush with each other and configured such that a part of one surface of the mask M is placed on the upper surface 20a of the first substrate 20 and another part of the surface of the mask M is placed on the upper surface 30a of the second substrate 30 (refer to FIG. 5A).

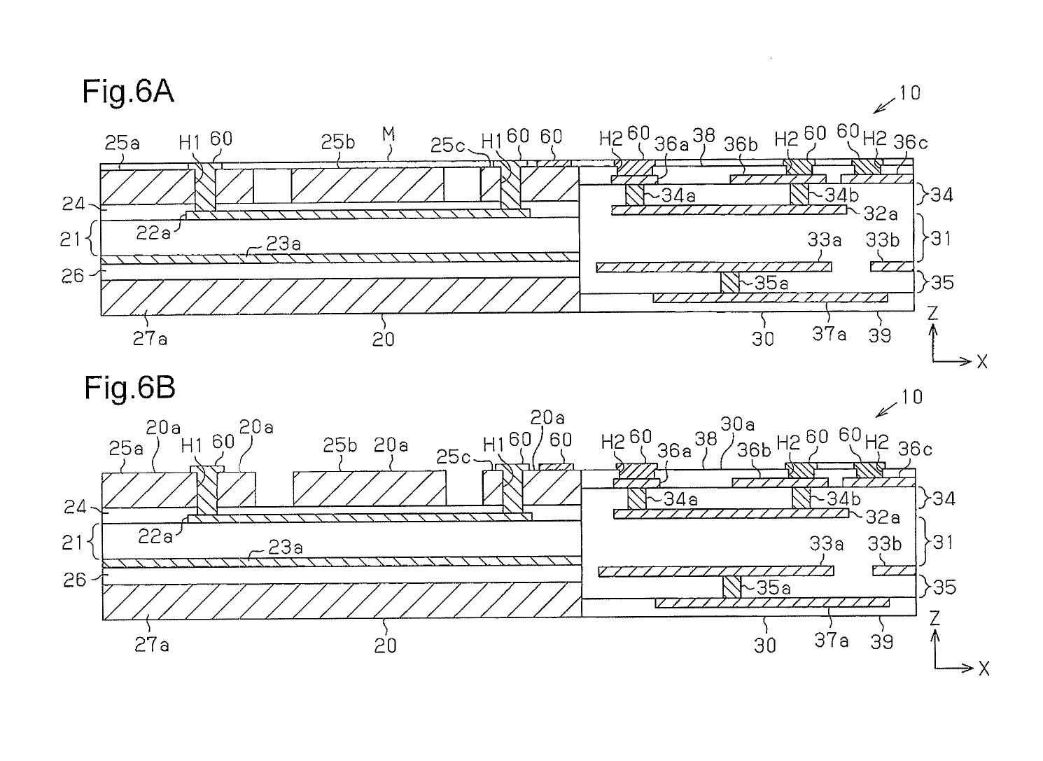

After the wiring board 10 is obtained in this way, the metal mask M is placed on the top surface of the wiring board 10, i.e. the upper surfaces 20a and 30a of the substrates 20 and 30 as shown in FIG. 5B. The surface of the metal mask M has a part placed on the upper surface 20a of the first substrate 20 and another part placed on the upper surface 30a of the second substrate 30. Then, solder 60 is applied onto the first substrate 20 and the second substrate 30 via the metal mask M as shown in FIG. 6A. In particular, the cream solder 60 is applied into the solder holes H1 and H2 at a time.

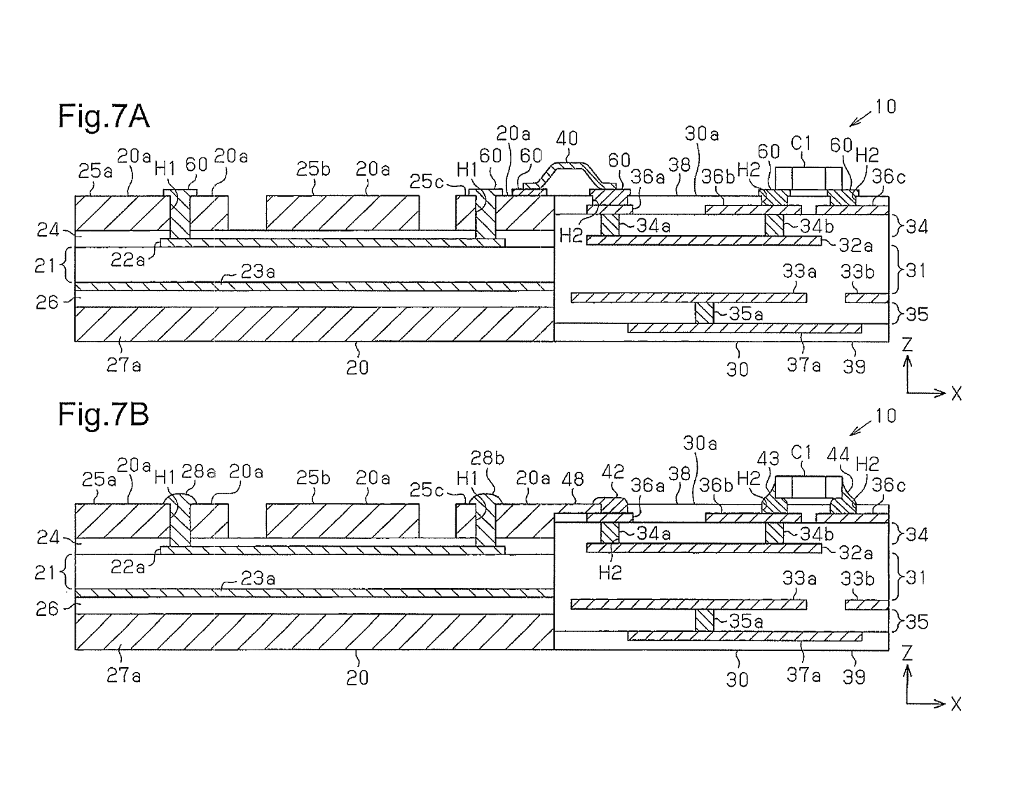

After that, the mask M is removed as shown in FIG. 6B. The chip C1 and the jumper wire 40 as components are placed on at least a part of the applied solder 60 as shown in FIG. 7A.

The chip C1 and the jumper wires 40 and 45 as components are mass-soldered by reflowing solder as shown in FIG. 2. In other words, the jumper wire 40 connects the thick copper pattern 25c of the substrate 20 with the wiring pattern 36a of the substrate 30 via the solder 41 and 42. Similarly, the jumper wire 45 connects the first substrate 20 with the second substrate 30.

Thus, the two substrates 20 and 30 have unique outlines that match each other and are integrated by hardening the adhesive 53 as liquid resin.

The two substrates 20 and 30 are designed to have uniform heights. This design enables mass-solder printing, thereby reducing production costs.

In addition, the design enables the mask of the two substrates 20 and 30 to have a flush surface. If the substrates 20 and 30 had different heights, a step at the connection between the substrates 20 and 30 would necessitate a step in the mask in accordance with the step at the connection. This would require positioning of the substrates 20 and 30 not only in the horizontal direction but also in the vertical direction.

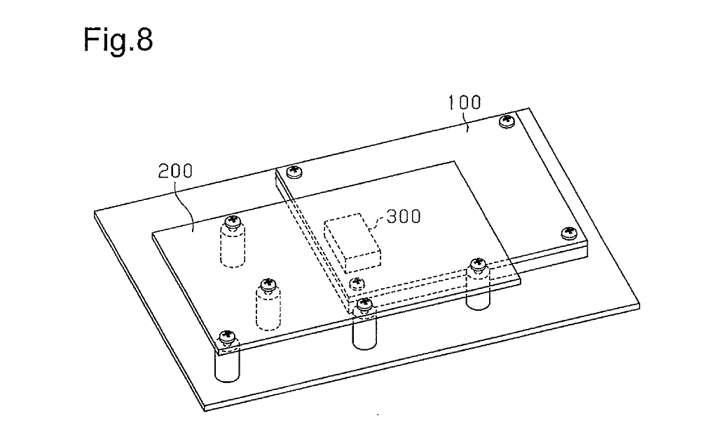

The jumper wires 40 and 45 are mounted between the substrates 20 and 30 when components are mounted. This enables electrical connection between the substrates 20 and 30. In particular, the wiring board shown in FIG. 8, which is described in the Background Art section, needs a separate component for connecting the substrates 100 and 200, such as a connector or a bus bar. This increases production costs. However, according to the present embodiment, the jumper wires 40 and 45 are mass-soldered to the wiring board, thereby reducing production costs.

The above illustrated embodiment achieves the following advantages.

(1) The wiring board 10 is configured such that the first substrate 20, which has the solder holes H1 in the upper surface 20a, is coupled to the second substrate 30, which has the solder holes H2 in the upper surface 30a. In a broad sense, the first substrate 20, which includes at least the first surface having the solder holes H1, is coupled to the second substrate 30, which includes at least the first surface having the solder holes H2. When the first substrate 20 and the second substrate 30 are electrically connected with each other, the upper surface 20a of the first substrate 20, which has solder holes, is flush with the upper surface 30a of the second substrates 30, which has solder holes. In other words, the first substrate 20 and the second substrate 30 are coupled to each other to have solder joining surfaces that are flush with each other. This enables mass-soldering to a plurality of substrates, the substrates 20 and 30, by applying cream solder at a time.

(2) Components are mass-soldered to at least one of the first substrate 20 and the second substrate 30. Thus, components can be mass-soldered to a plurality of substrates, the substrates 20 and 30.

(3) The positioning portions 50 each include the projection 51, which is arranged in the second substrate 30, and the recess 52, which is arranged in the first substrate 20 and engages with the projection 51. In a broad sense, each positioning portion 50 includes the projection 51, which is arranged in one of the first substrate 20 and the second substrate 30, and the recess 52, which is arranged in the other configuration facilitates forming of the positioning portion 50.

The positioning portion 50, which is formed in at least one of the first substrate 20 and the second substrate 30, enables positioning of the substrates 20 and 30.

(4) The positioning portion 50 has the space S1 for placing a connection member. Thus, the first substrate 20 and the second substrate 30 are easily connected to each other using the connection member (53).

(5) The connection member is the adhesive 53. Thus, the first substrate 20 and the second substrate 30 are easily connected to each other using the adhesive 53.

(6) The recess 52 of the first substrate 20 is coupled to the projection 51 of the second substrate 30 such that the substrates 20 and 30 have solder joining surfaces that are flush with each other. This allows the mask of the first substrate 20 and the second substrate 30 to have a flush surface on the solder joining surfaces of the first and second substrates 20 and 30. This facilitates the placement of a mask on the first substrate 20 and the second substrate 30.

(7) A mass-soldered component is the jumper wire 40, which electrically connects the first substrate 20 and the second substrate 30 with each other. Thus, the first substrate 20 and the second substrate 30 can be electrically connected with each other with the jumper wire 40.

(8) A mass-soldered component is the chip C1 as a surface-mount component. Thus, the chip C1 as a surface-mount component can be soldered.

(9) The wiring board production method includes a coupling process, a first placement process, an application process, a removal process, a second placement process, and a reflowing process. The coupling process couples the first substrate 20 to the second substrate 30 such that the first surface 20a of the first substrate 20, which has the solder holes H1, is flush with the first surface 30a of the second substrate 30, which has the solder holes H2. The first placement process places the mask M on the first surface 20a of the first substrate 20, which has the solder holes H1, and the first surface 30a of the second substrate 30, which has the solder holes H2. The application process applies the solder 60 onto the first substrate 20 and the second substrate 30 through the mask M. The removal process removes the mask M. The second placement process places components (the jumper wire 40 and the chip C1 as a surface-mount component) on at least a part of the applied solder 60. The reflowing process mass-solders the components (the jumper wire 40 and the chip C1) to the substrates 20 and 30 by reflowing solder. Thus, mass-soldering to a plurality of substrates, the substrates 20 and 30, is possible.

The present invention is not restricted to the illustrated embodiment but may be embodied, for example, in the following forms.

Any coupling means may be employed as long as the first substrate 20 is coupled to the second substrate 30. In particular, coupling means such as bonding and crimping may couple the first and second substrates 20 and 30.

The positioning portion 50 does not necessarily position the first and second substrates 20 and 30 using the projection-recess relationship of the projection 51 and the recess 52. For example, another member may be used to prevent mechanical displacement of the first and second substrates 20 and 30. The liquid adhesive 53, which fills the positioning portion 50, does not necessarily need to be used.

In FIG. 2, the upper surface 20a of the first substrate 20 is a soldered surface, and the upper surface 30a of the second substrate 30 is a soldered surface. The upper surface 20a of the first substrate 20 is flush with the upper surface 30a of the second substrate 30, and the bottom surface of the first substrate 20 is flush with the bottom surface of the second substrate 30. However, this is not the only form. For example, the bottom surface of the first substrate 20 does not necessarily need to be flush with the bottom surface of the second substrate 30. A modification is possible as long as at least the first surface 20a is a solder joining surface in the first substrate 20, at least the second surface 30a is a solder joining surface in the second substrate 30, and the first substrate 20 and the second substrate 30 are coupled to each other such that the solder joining surfaces are flush with each other.

Furthermore, the bottom surface of the first substrate 20 may be a soldered surface, and the bottom surface of the second substrate 30 may be a soldered surface. In this case, the bottom surface of the first substrate 20 is made flush with the bottom surface of the second substrate 30.

The substrates 20 and 30 may be any types of substrates. The substrates 20 and 30 may be, e.g., multilayered substrates, double-sided substrates, or single-sided substrates.

A metal component as a connection member may be inserted into the space S1 of the positioning portion 50 and plastically deformed.

The jumper wire 40 electrically connects the first substrate 20 and the second substrate 30 with each other. Instead of the jumper wire 40, the thick copper pattern 25c of the substrate 20 may have a portion extending from the lateral side of the substrate 20 as shown in FIG. 7B. The extending portion 48 is joined to the wiring pattern 36a of the substrate 30 with the solder 42.

Instead of the jumper wires 40 and 45, a bus bar may electrically connect the first substrate 20 and the second substrate 30 with each other.

1. A wiring board comprising:
a first substrate including a first surface, wherein a solder hole is arranged at least in the first surface; and
a second substrate including a first surface, wherein a solder hole is arranged at least in the first surface, and the second substrate is coupled to the first substrate, wherein
the first substrate and the second substrate are electrically connected with each other,
the first surface of the first substrate and the first surface of the second substrate are flush with each other and configured such that a part of one surface of a mask is placed on the first surface of the first substrate and another part of the surface of the mask is placed on the first surface of the second substrate.

2. The wiring board according to claim 1, further comprising a component that is mass-soldered to at least one of the first substrate and the second substrate.

3. The wiring board according to claim 1, further comprising a positioning portion arranged in at least one of the first substrate and the second substrate.

4. The wiring board according to claim 3, wherein the positioning portion includes a projection that is arranged in one of the first substrate and the second substrate and a recess that is arranged in the other one of the first and second substrates and engages with the projection.

5. The wiring board according to claim 3, wherein the positioning portion has a space in which a connection member is placed.

6. The wiring board according to claim 5, wherein the connection member includes adhesive.

7. The wiring board according to claim 2, wherein the component includes a jumper wire, which electrically connects the first substrate and the second substrate with each other.

8. The wiring board according to claim 2, wherein the component includes a surface-mount component.

9. A wiring board production method comprising:
a coupling process for coupling a first substrate to a second substrate such that a first surface of the first substrate, which has a solder hole, is flush with a first surface of the second substrate, which has a solder hole;
a first placement process for placing a mask on the first surface of the first substrate and the first surface of the second substrate, wherein a part of one surface of the mask is placed on the first surface of the first substrate and another part of the surface of the mask is placed on the first surface of the second substrate;
a solder application process for applying solder onto the first substrate and the second substrate through the mask;
a removal process for removing the mask;
a second placement process for placing a component on at least a part of the applied solder; and
a reflowing process for mass-soldering the component by reflowing.
